(19) United States
(12) Patent Application Publication
(10) Pub. No.: US 2025/0125280 A1
(43) Pub. Date: Apr. 17, 2025

(54) SEMICONDUCTOR PACKAGE AND SEMICONDUCTOR PACKAGE MANUFACTURING METHOD

(71) Applicant: Samsung Electronics Co., Ltd., Suwon-si (KR)

(72) Inventors: Taejun KIM, Suwon-si (KR); Geunwoo KIM, Suwon-si (KR)

(73) Assignee: Samsung Electronics Co., Ltd., Suwon-si (KR)

(21) Appl. No.: 18/760,146

(22) Filed: Jul. 1, 2024

(30) Foreign Application Priority Data
Oct. 16, 2023 (KR) 10-2023-0137405

(51) Int. Cl. H01L 23/552; H01L 21/285; H01L 23/00; H01L 23/498; H01L 25/065; H01L 25/10; H01L 25/18; H10B 80/00

(52) U.S. Cl. CPC H01L 23/552; H01L 21/2855; H01L 23/49816; H01L 24/16; H01L 24/32; H01L 24/48; H01L 24/73; H01L 25/0657; H01L 25/105; H01L 25/18; H01L 2224/16225; H01L 2224/32225; H01L 2224/48145; H01L 2224/48227; H01L 2224/73204; H01L 2924/1431; H01L 2924/1815; H10B 80/00

(57) ABSTRACT

A semiconductor package may include: a wiring structure having a structure in which at least one insulating layer and at least one wiring layer are alternately stacked; a semiconductor chip disposed to vertically overlap the wiring structure; and a conductive shielding layer accommodating the semiconductor chip, and covering a portion of a side surface of the wiring structure to be connected to a ground of the at least one wiring layer, wherein the other portion of the side surface of the wiring structure may not be covered by the conductive shielding layer.

### CROSS-REFERENCE TO RELATED APPLICATION

This application claims the priority and benefit of Korean Patent Application Nos. 10-2023-0137405, filed on Oct. 16, 2023, with the Korean Intellectual Property Office, the disclosure of which is incorporated herein by reference in its entirety.

### BACKGROUND

### 1. Field

The present inventive concepts relates to a semiconductor chip, a semiconductor package, and a method of manufacturing a semiconductor chip.

### 2. Description of Related Art

As electronic devices become lighter and are implemented with high performance, miniaturization and high performance are also required in a field of semiconductor packages (e.g., High-Bandwidth Memory, non-memory semiconductor package). An operation of a semiconductor chip that may be included in a semiconductor package (e.g., signal transmission/reception processing, information storage processing, logic operation processing, circuit operation, and the like) may be affected by electromagnetic noise externally of the semiconductor package. Accordingly, the semiconductor package may be more advantageous for miniaturization and high performance by improving electromagnetic shielding reliability.

### SUMMARY

Some example embodiments of inventive concepts provide a semiconductor package and a method of manufacturing a semiconductor package that can improve electromagnetic shielding reliability.

Some example embodiments of inventive concepts relate to a wiring structure having a structure in which at least one insulating layer and at least one wiring layer are alternately stacked; a semiconductor chip to vertically overlap the wiring structure; and a conductive shielding layer accommodating the semiconductor chip, and covering a portion of a side surface of the wiring structure to be connected to a ground of the at least one wiring layer, wherein another portion of the side surface of the wiring structure may not be covered by the conductive shielding layer.

Some example embodiments of inventive concepts relate to a method of manufacturing a semiconductor package, including disposing a semiconductor package so that the portion of a semiconductor package on which a conductive shielding layer is not formed is immersed in liquid; and forming the conductive shielding layer on another portion of the semiconductor package, such that a portion of the conductive shielding layer covers the another portion of the semiconductor package immersed in liquid.

Some example embodiments of inventive concepts relate to a method of manufacturing a semiconductor package, including disposing a semiconductor package on an upper surface of a film on which a coating layer is formed on a portion of the upper surface, so that a portion of the semiconductor package is in contact with a side surface of the coating layer; and forming a conductive shielding layer to cover another portion of the semiconductor package that is not in contact with the side surface of the coating layer.

### BRIEF DESCRIPTION OF DRAWINGS

The above and other aspects, features, and advantages of the present inventive concepts will be more clearly understood from the following detailed description taken in conjunction with the accompanying drawings, in which:

FIG. 1 is a cross-sectional view illustrating a semiconductor package according to an example embodiment of the present inventive concepts;

FIGS. 2A to 2C are cross-sectional views and plan views illustrating an operation of disposing a semiconductor package in a method of manufacturing a semiconductor package according to an example embodiment of the present inventive concepts;

FIGS. 2D to 2F are cross-sectional views illustrating an operation of forming a conductive shielding layer in the method of manufacturing a semiconductor package according to an example embodiment of the present inventive concepts using liquid;

FIGS. 3A to 3C are cross-sectional views illustrating an operation of forming a conductive shielding layer in the method of manufacturing a semiconductor package according to an example embodiment of the present inventive concepts using a coating layer;

FIGS. 4A to 4C are cross-sectional views illustrating first, second, and third conductive shielding layers of the semiconductor package according to an example embodiment of the present inventive concepts;

FIG. 5A is a cross-sectional view illustrating a fan-in structure of the semiconductor package according to an example embodiment of the present inventive concepts;

FIG. 5B is a cross-sectional view illustrating a Package on Package (POP) structure of the semiconductor package according to an example embodiment of the present inventive concepts; and

FIG. 5C is a cross-sectional view illustrating a structure in which a plurality of semiconductor chips are vertically stacked in the semiconductor package according to an example embodiment of the present inventive concepts.

### DETAILED DESCRIPTION

The detailed description of the present inventive concepts refers to the accompanying drawings which, by way of example, illustrate some example embodiments in which the present inventive concepts may be practiced. These example embodiments are described in sufficient detail to enable one skilled in the art to practice the present inventive concepts. It should be understood that the various example embodiments of the present inventive concepts are different from each other but are not necessarily mutually exclusive. For example, specific shapes, structures, and characteristics described herein may be implemented in one example embodiment and/or in another example embodiment without departing from the spirit and scope of the inventive concepts. Additionally, it should be understood that the location or arrangement of individual components within each disclosed example embodiment may be changed without departing from the spirit and scope of the inventive concepts. Accordingly, the detailed description set forth below is not to be taken in a limiting sense, and the scope of the present inventive concepts is limited only by the appended claims, along with all equivalents as claimed by those claims. Like reference numbers in the drawings indicate the same or similar function throughout the various aspects.

As described herein, an element that is “on” another element may be above or beneath or adjacent (e.g., horizontally adjacent) to the other element. An element that is on another element may be directly on the other element, such that the element is in direct contact with the other element. An element that is on another element may be indirectly on the other element, such that the element is isolated from direct contact with the other element by one or more interposing spaces and/or structures.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, example embodiments of the present inventive concepts will be described in detail with reference to the accompanying drawings so that those skilled in the art can easily practice the present inventive concepts.

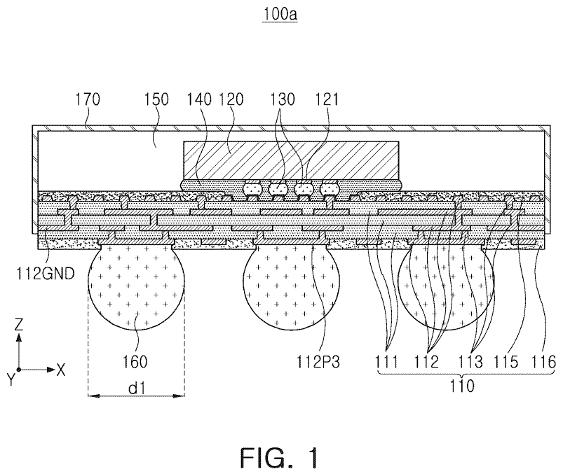

Referring to FIG. 1, a semiconductor package 100a according to an example embodiment of the present inventive concepts may include a wiring structure 110, a semiconductor chip 120, and a conductive shielding layer 170, and may further include an encapsulant 150 and/or a plurality of bumps 160.

The wiring structure 110 may have a structure in which at least one insulating layer 111 and at least one wiring layer 112 are alternately stacked. For example, the wiring structure 110 is a support substrate on which the semiconductor chip 120 is mounted, and may be a package substrate for wiring a connection pad 121 of the semiconductor chip 120. The package substrate may include a printed circuit board (PCB), a ceramic substrate, a glass substrate, a tape wiring substrate, and the like. The wiring structure 110 may include insulating layers 111, wiring layers 112, wiring vias 113, an upper solder mask layer 115, and a lower solder mask layer 116. In some example embodiments, the number of layers of the insulating layers 111 and the wiring layers 112 forming a wiring structure 110 may be variously changed. In some example embodiments, the wiring structure 110 may be an interposer substrate, for example, an organic interposer. In some example embodiments, the wiring structure 110 may be a module substrate, and in some example embodiments, the semiconductor chip 120 may be a semiconductor structure such as a semiconductor package.

The insulating layers 111 may include an insulating material, and may include, for example, a thermosetting resin such as epoxy resin or a thermoplastic resin such as polyimide. For example, the insulating layers 111 may include a photosensitive insulating material such as a Photoimageable Dielectric (PID) resin. Alternatively or additionally, the insulating layers 111 may include a resin mixed with an inorganic filler, for example, Ajinomoto Build-up Film (ABF). Alternatively or additionally, the insulating layers 111 may include prepreg, flame retardant (FR-4), or bismaleimide triazine (BT). The insulating layers 111 may include the same or different materials. Boundaries between the insulating layers 111 may not be distinguishable depending on (or based on) the materials and processes for forming each layer.

The wiring layers 112 and the wiring vias 113 may form an electrical path. The wiring layers 112 and the wiring vias 113 may wire the semiconductor chip 120 to a region outside the semiconductor chip 120, for example, to a fan-out region, not overlapping the semiconductor chip 120 in a Z-direction. Accordingly, the semiconductor package 100a of some example embodiments may be referred to as a fan-out semiconductor package. However, the form of the semiconductor package is not limited thereto, and in some example embodiments, the semiconductor package 100a may form a fan-in semiconductor package. The wiring layers 112 and the wiring vias 113 may include a ground pattern, a power pattern, and a signal pattern. The wiring layers 112 may be disposed in a line shape on an X-Y plane, and the wiring vias 113 may have a cylindrical shape having a side surface inclined so as to be narrow toward a lower portion or an upper portion thereof. The wiring vias 113 are illustrated as filled vias in which an interior thereof is filled with a conductive material, but example embodiments are not limited thereto. For example, the wiring vias 113 may have a form of conformal vias in which a metal material extends along an inner wall of a via hole.

The wiring layers 112 and wiring vias 113 may include a conductive nickel (Ni), lead (Pb), titanium (Ti), or alloys thereof, but example embodiments are not limited thereto. Depending on (or based on) a width of wirings of the wiring layers 112 or a gap between the wirings (e.g., 10 μm to 100 μm), the wirings of the wiring layers 112 may be implemented as a redistribution line. FIG. 1 illustrates a wiring structure 110 in which uppermost and lowermost wiring layers among the wiring layers 112 are protruded trace substrate (PTS) structures protruding up and down from uppermost and lowermost insulating layers 111, but depending on (or based on) the design, the wiring structure 110 may be an embedded trace substrate (ETS).

The wiring layers 112 may include a plurality of lower pads 112P3 exposed through a lower solder mask layer 116. The plurality of lower pads 112P3 may be disposed on the lowest insulating layer among the insulating layers 111, and the plurality of lower pads 112P3 may be exposed downwardly through a plurality of upper and lower passages of the lower solder mask layer 116 and electrically connected to the plurality of bumps 160. Each of the plurality of lower pads 112P3 may have a circular or polygonal upper and lower surface. As a diameter d1 of each of the plurality of bumps 160 increases, the width of each of the plurality of lower pads 112P3 may also increase.

The upper and lower solder mask layers 115 and 116 may be solder resist layers protecting the wiring layer 112 from external physical and chemical damage. The upper and lower solder mask layers 115 and 116 may include an insulating material, and may include, for example, prepreg, Ajinomoto Build-up Film (ABF), FR-4, BT, or Photo Solder Resist (PSR), but example embodiments are not limited thereto.

The semiconductor chip 120 may be disposed to vertically overlap the wiring structure 110. The semiconductor chip 120 may include connection pads 121 on a lower surface thereof. The semiconductor chip 120 may be mounted on an upper surface of the wiring structure 110 in a flip-chip bonding method. The semiconductor chip 120 may include a device layer or active layer located below the connection pads 121 and on which an integrated circuit (IC) is disposed. The semiconductor chip 120 may include a logic semiconductor chip and/or a memory semiconductor chip. The logic semiconductor chip may be a micro-processor, for example, a Central Processing Unit (CPU), a Graphic Processing Unit (GPU), a Field Programmable Gate Array (FPGA), an application processor (AP), a digital signal processor, a cryptographic processor, a controller, or an application specific integrated circuit (ASIC), but example embodiments are not limited thereto. The memory semiconductor chip may be a volatile memory such as dynamic random access memory (DRAM), static random access memory (SRAM), or the like, or a non-volatile memory such as flash memory, or the like, but example embodiments are not limited thereto.

A body portion of the semiconductor chip 120 may include silicon (Si), germanium (Ge), gallium arsenide (GaAs), and the like, and the connection pads 121 may include a conductive material such as tungsten (W), aluminum (Al), copper (Cu), or the like, but example embodiments are not limited thereto. The connection pads 121 may be pads of a bare chip, for example, aluminum (Al) pads, but according to some example embodiments, the connection pads 121 may be pads of a packaged chip, for example, a copper (Cu) pad. The connection pads 121 may be electrically connected to the wiring layer 112 of the wiring structure 110 through a plurality of chip bumps 130. Being electrically connected may mean providing at least a portion of a path through which signals are transmitted. In some example embodiments, the connection pads 121 may be disposed in the body portion of the semiconductor chip 120 so that a lower surface thereof forms a lower surface of the semiconductor chip 120. In some example embodiments, a passivation layer exposing the connection pads 121 may be further disposed on the lower surface of the semiconductor chip 120. The passivation layer may include a silicon oxide film and/or a silicon nitride film.

The conductive shielding layer 170 may accommodate the semiconductor chip 120, and cover a portion of a side surface (e.g., upper side surface) of the wiring structure 110 to be connected to a ground 112GND of at least one wiring layer 112. In some example embodiments, accepting may mean that the conductive shielding layer 170 surrounds the semiconductor chip 120 and overlaps the semiconductor chip 120 vertically. For example, the conductive shielding layer 170 may have a shape of a cap, and the semiconductor chip 120 may be inserted into an accommodation space of the cap. FIG. 1 illustrates a conformal shielding structure of the conductive shielding layer 170, but depending on (or based on) the design, the conductive shielding layer 170 may have a compartment shielding structure.

Since conductivity of the conductive shielding layer 170 may reflect and/or attenuate electromagnetic noise trying to pass through the conductive shielding layer 170, the conductive shielding layer 170 may electromagnetically shield to reduce the influence of electromagnetic noise outside the semiconductor package 100a on the semiconductor chip 120.

The conductive shielding layer 170 may be connected to a ground 112GND of at least one wiring layer 112, the conductive shielding layer 170 may have electrical stability and further improve electromagnetic shielding performance. For example, a portion of the wiring layers 112 of the wiring structure 110 may be signal/power wirings through which a signal or power flows, and other portions of the wiring layers 112 may be a ground plate and/or ground wiring. The ground plate may surround signal/power wirings. The ground plate and/or ground wiring of the wiring layers 112 may be exposed to a side surface of the wiring structure 110, and the conductive shielding layer 170 may be connected to the ground plate and/or ground wiring of the wiring layers 112 through the side surface of the wiring structure 110.

An edge portion of the conductive shielding layer 170 may be the lowest portion of the conductive shielding layer 170, and may be the most physically vulnerable portion (or may be a physically vulnerable portion) of the conductive shielding layer 170. For example, the conductive shielding layer 170 may be formed by separation or cutting in a wider state, and the separation or cutting may cause physical vulnerability (e.g., burring) in the edge portion of the conductive shielding layer 170. The physical vulnerability (e.g., burring) may be a limiting factor in the reliability of the conductive shielding layer 170. Alternatively or additionally, even without the separation or cutting, if the edge portion of the conductive shielding layer 170 covers a lower corner of the wiring structure 110, the edge portion of the conductive shielding layer 170 itself may become a physical vulnerability.

The other portion of the side surface of the wiring structure 110 (e.g., a lower side surface) may be covered by the conductive shielding layer 170 and exposed. Accordingly, the edge portion of the conductive shielding layer 170 can be prevented from causing physical vulnerability such as a burr (or the likelihood of causing a physical vulnerability such as a burr can be reduced), and the edge of the conductive shielding layer 170 itself may be all prevented from becoming a physical vulnerability (or the likelihood of the edge of the conductive shielding layer 170 itself becoming a physical vulnerability can be reduced). Accordingly, the reliability of the conductive shielding layer 170 can be increased.

For example, the lowermost portion of the conductive shielding layer 170 may be located in an upper level than the lowermost portion of the wiring structure 110. A portion of a side surface of at least one insulating layer 111 (e.g., an insulating layer located on the lower side of the insulating layers or an insulating layer located on the lower side of the wiring layer 112 exposed to the side surface) may not be covered by the conductive shielding layer 170 and exposed. A side surface of the lower solder mask layer 116 may be exposed without being covered by the conductive shielding layer 170.

Since the encapsulant 150 is disposed on an upper side of the wiring structure 110, the conductive shielding layer 170 can completely cover an upper surface and a side surface of the encapsulant 150 (or the conductive shielding layer 170 can cover an upper surface and a side surface of the encapsulant 150). The encapsulant 150 may encapsulate and protect the semiconductor chip 120 on the upper surface of the wiring structure 110. The encapsulant 150 may be disposed to cover side surfaces and an upper surface of the semiconductor chip 120 and may directly contact the side surfaces and upper surface of the semiconductor chip 120, but the present inventive concepts are not limited thereto. The encapsulant 150 may include a molding material such as Epoxy Molding Compound (EMC), but the present inventive concepts are not limited thereto. For example, the encapsulant 150 may include an insulating material, such as a thermosetting resin such as an epoxy resin, a thermoplastic resin such as polyimide, an inorganic filler, and/or may also include prepreg containing glass fibers, ABF, FR-4, BT, or PID, but example embodiments are not limited thereto.

A non-conductive film layer 140 may be disposed between the semiconductor chip 120 and the wiring structure 110 to surround the plurality of chip bumps 130. The non-conductive film layer 140 may also be referred to as an underfill layer. The non-conductive film layer 140 may include a non-conductive polymer, for example, a non-conductive paste (NCP). The non-conductive film layer 140 may be formed on the lower surface of the semiconductor chip 120 or the upper surface of the wiring structure 110 during a reflow process or TCB process, and then fill a space between the semiconductor chip 120 and the wiring structure 110. Accordingly, the non-conductive film layer 140 may have a shape that protrudes outwardly of end portions of the semiconductor chip 120. A length at which the non-conductive film layer 140 protrudes horizontally from the side surfaces of the semiconductor chip 120 may be greater at a center thereof in a thickness direction than at the lower surface and the upper surface thereof.

The plurality of bumps 160 may be electrically connected to at least one wiring layer 112 and arranged under at least one insulating layer 111. The plurality of bumps 160 may be electrically connected to at least one wiring layer 112 and arranged under at least one insulating layer 111. The plurality of bumps 160 may physically and/or electrically connect a semiconductor package 100a to an external device such as a main board, or may be electrically connected to an additional semiconductor package below the semiconductor package 100a.

The plurality of bumps 160 may have a larger size and diameter than the plurality of chip bumps 130. Each of the plurality of bumps 160 and the plurality of chip bumps 130 may include a low-melting point (e.g., lower melting point than a melting point of a metal included in the wiring layer 112) metal, such as lead (Pb) or bismuth (Bi), tin (Sn) and an alloy containing tin (Sn) (Sn—Ag—Cu), or the like, but the present inventive concepts are not limited thereto. Each of the plurality of bumps 160 and the plurality of chip bumps 130 may have a land, ball, or pin shape and may be formed of a single layer or multiple layers. For example, the plurality of bumps 160 may be solder balls. At a temperature higher than the melting point, the plurality of bumps 160 and the plurality of chip bumps 130 may have a fluid state by a reflow process or a thermal compression bonding (TCB) process. Thereafter, as the temperature decreases, the plurality of bumps 160 and the plurality of chip bumps 130 may be connected to and fixed to pads of the wiring layer 112.

The semiconductor package 100a may be a high-bandwidth memory (HBM) semiconductor package, and may include a plurality of bumps 160 having a diameter dl longer than each diameter of bumps of other types of semiconductor packages (e.g., AP, NAND). For example, the diameter d1 of each of the plurality of bumps 160 may exceed 200 μm, or may exceed 200 μm and be less than 300 μm (e.g., 250 μm).

As the diameter d1 of each of the plurality of bumps 160 is longer, a degree of freedom in a process of forming the conductive shielding layer 170 may become narrower. For example, as the diameter d1 of each of the plurality of bumps 160 is longer, the efficiency of the process of forming the conductive shielding layer 170 after impregnating the plurality of bumps 160 with an ultraviolet tape may decrease.

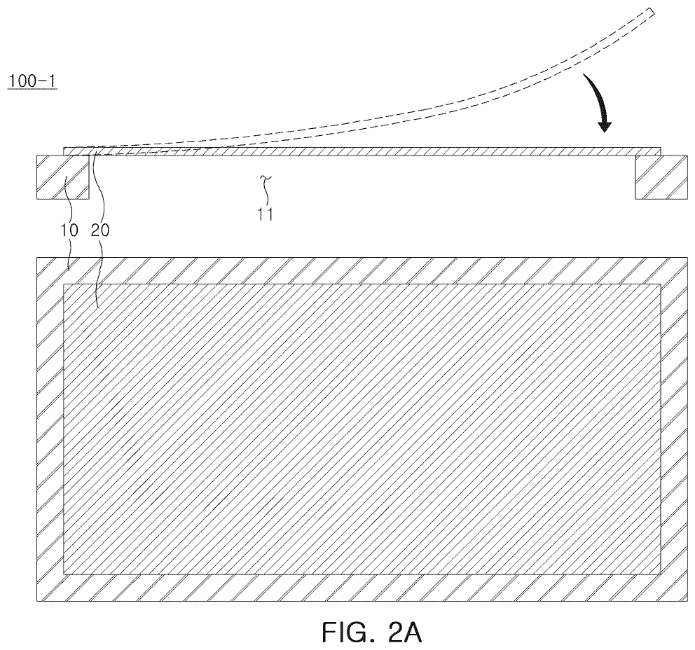

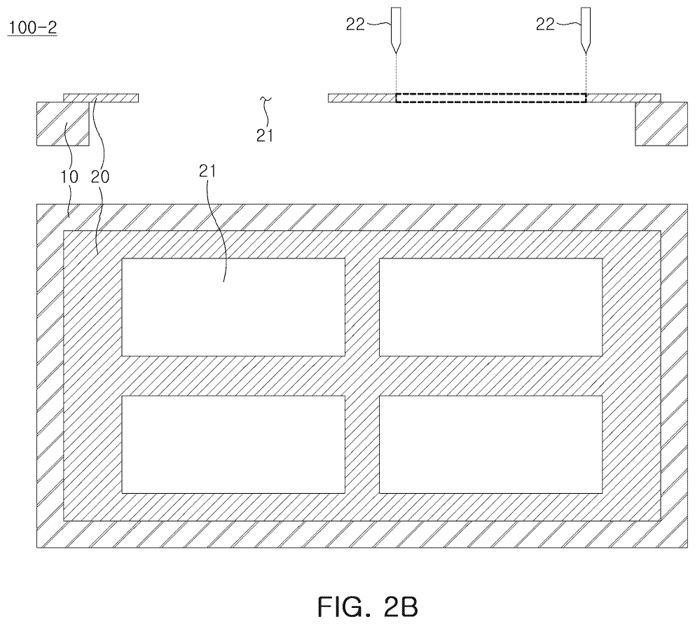

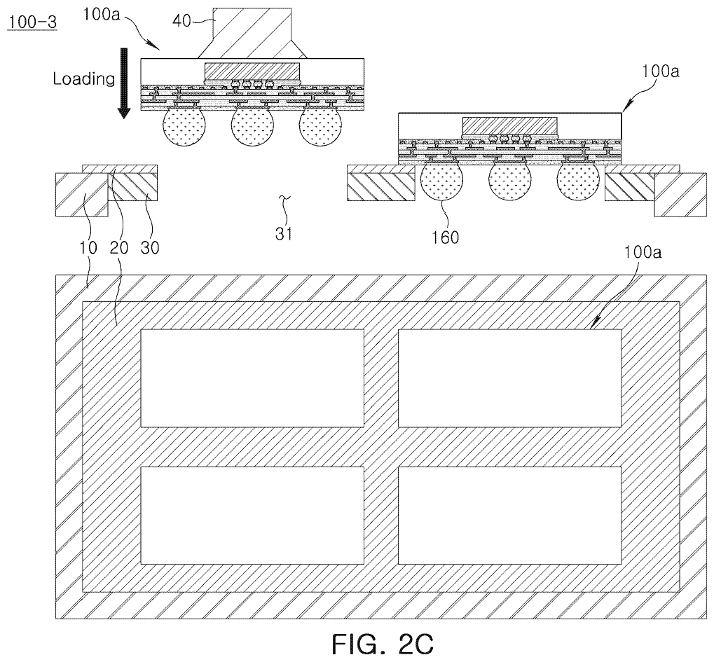

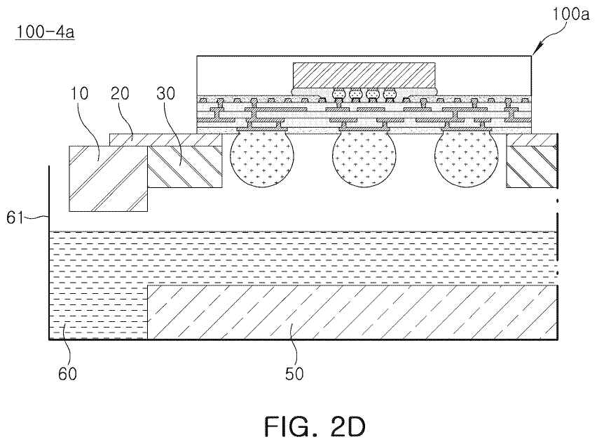

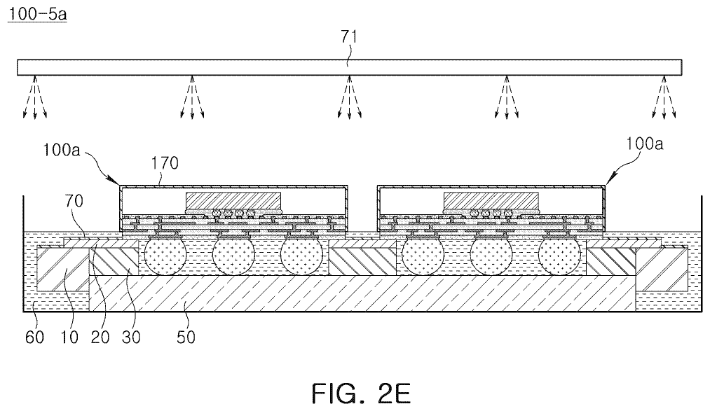

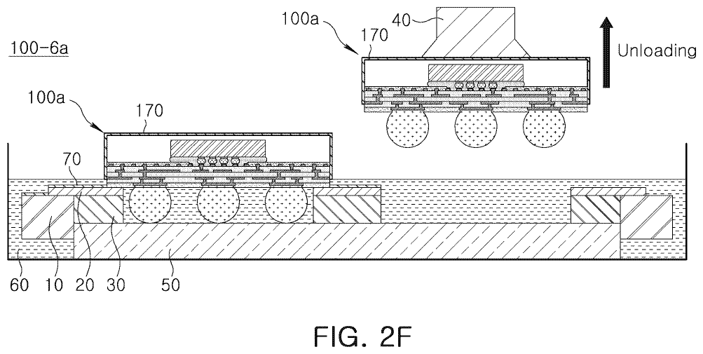

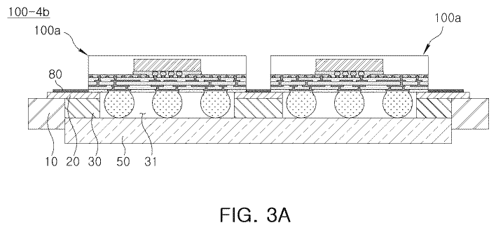

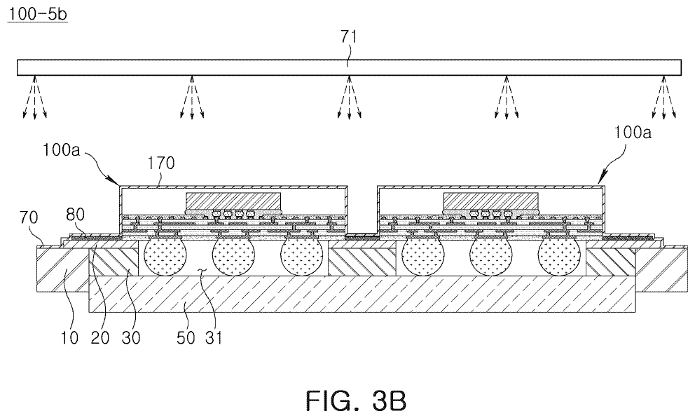

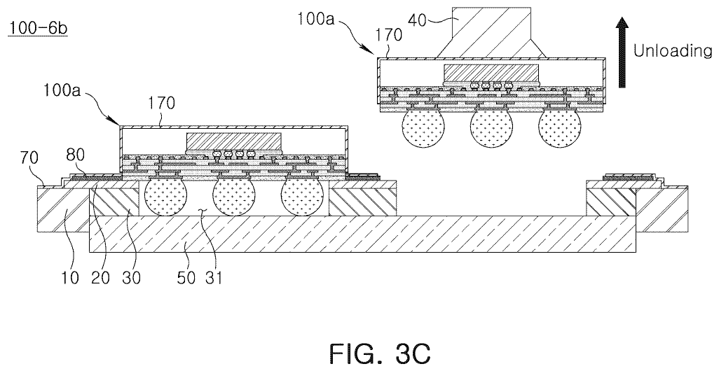

Hereinafter, a method of manufacturing a semiconductor package of FIGS. 2A to 3C may increase the efficiency of the process of forming the conductive shielding layer 170 substantially, regardless of the diameter d1 of each of the plurality of bumps 160, and may be efficient to implement a structure in which the conductive shielding layer 170 does not cover a lower side surface of the wiring structure 110.

Referring to FIGS. 2A to 2F, a method of manufacturing semiconductor packages 100-1, 100-2, 100-3, 100-4a, 100-5a, and 100-6a may include: disposing a semiconductor package 100a so that a portion (e.g., lower portion) of the semiconductor package 100a on which the conductive shielding layer 170 is not formed is immersed in a liquid 60, and forming a conductive shielding layer 170 covering the other portion (e.g., upper portion) of the semiconductor package 100a of which a portion (e.g., lower portion) is immersed in liquid.

Referring to FIG. 2A, the semiconductor package manufacturing method 100-1 may include disposing a film 20 on an upper surface of a ring frame 10. The ring frame 10 may have a shape surrounding an internal space 11. A material of the ring frame 10 is not particularly limited, and may include a material with relatively strong strength (e.g., stronger than the film 20) to stably support the plurality of semiconductor packages 100a. For example, the film 20 may include a material that is highly flexible and efficient to process, such as polyimide.

Referring to FIG. 2B, the semiconductor package manufacturing method 100-2 may include forming a plurality of holes 21 in the film 20. The plurality of holes 21 may overlap vertically in the internal space 11, and may be formed by cutting edges of the plurality of holes 21 using a cutter 22. For example, the cutter 22 may form a plurality of holes 21 using a laser or blade.

Referring to FIG. 2C, the semiconductor package manufacturing method 100-3 may include disposing the semiconductor package 100a so as to overlap vertically with the hole 21 of the film 20 having the hole 21 of FIG. 2B, and inserting the plurality of bumps 160 of the package 100a into the hole 31. The stencil 30 may be disposed on a lower side of a region of the film 20 that does not overlap vertically with the ring frame 10 to support the film 20 upwardly. A combination of a hole in the stencil 30 and the hole in the film 20 may be a hole 31.

As the plurality of bumps 160 are inserted into the hole 31, an edge of a lower surface of the semiconductor package 100a may directly contact an upper surface of the film 20. For example, the semiconductor package 100a may be disposed on a portion of the upper surface of the film 20 to be immersed in liquid, to be described later. For example, a pick and place device 40 may pick the semiconductor package 100a and move the semiconductor package 100a onto the film 20 and the hole 31.

Referring to FIG. 2D, a method of manufacturing a semiconductor package 100-4a may include disposing a combination of the semiconductor package 100a and the film 20 on an upper surface of the support member 50 immersed in liquid 60. For example, the support member 50 may have a plate shape, and may be disposed on a lower surface of a water tank 61. A material of each of the support member 50, the water tank 61, and the stencil 30 are not particularly limited, and may include a material having relatively strong strength (e.g., strength stronger than that of the film 20) to stably support the plurality of semiconductor packages 100a. The liquid 60 may be filled with a partial volume of an internal space of the water tank 61, and then the combination of the semiconductor package 100a and the film 20 may be immersed in the liquid 60.

Referring to FIG. 2E, a method of manufacturing a semiconductor package 100-5a may include forming a conductive shielding layer 170 through a sputtering process. A sputtering device 71 may deposit conductive materials on a surface of a portion of the semiconductor package 100a which is not immersed in the liquid 60 (e.g., upper portion). In some example embodiments, among the conductive materials provided by the sputtering device 71, the conductive materials 70 that have moved into the liquid 60 may sink in the liquid 60 due to higher specific gravity than the liquid 60. Accordingly, the conductive materials 70 may not accumulate on the surface of the portion (e.g., lower portion) of the semiconductor package 100a immersed in the liquid 60.

For example, the liquid 60 may be water containing a surfactant. Accordingly, since a phenomenon in which a portion of the conductive materials 70 floating on a water surface of the liquid 60 may be suppressed, a formation height of the conductive shielding layer 170 may be more accurately adjusted. The specific gravity of water may be 1 and may be lower than the specific gravity of conductive materials (e.g., copper—8, stainless steel—7.8).

Referring to FIG. 2F, a method of manufacturing a semiconductor package 100-6a may include separating the semiconductor package 100a from the film 20. An area immersed in the liquid 60 on a side surface of the semiconductor package 100a may be determined by a water level of the liquid 60 in the internal space of the water tank 61. Since the water level may be controlled by controlling an amount of liquid 60, the water level can be delicately controlled. Since the formation height of the conductive shielding layer 170 may be determined by the water level, the formation height thereof may be finely adjusted (or may be adjusted) by adjusting the water level.

A structure in which the conductive shielding layer 170 is connected to a ground of the semiconductor package 100a while exposing a lower side surface of the wiring structure of the semiconductor package 100a may require fine control (or may require control) of the formation height of the conductive shielding layer 170. In a method of manufacturing semiconductor packages 100-1, 100-2, 100-3, 100-4a, 100-5a, and 100-6a according to an example embodiment of the present inventive concepts, since the formation height of the conductive shielding layer 170 is finely adjusted (or is adjusted), since the structure in which the conductive shielding layer 170 is connected to a ground of the semiconductor package 100a while exposing a lower side surface of the wiring structure of the semiconductor package 100a may be stably formed (or may be formed), electromagnetic shielding reliability of the semiconductor package 100a may be improved.

Referring to FIGS. 2A to 2C and 3A to 3C, a method of manufacturing semiconductor packages 100-1,100-2,100-3, 100-4b, 100-5b, and 100-6b according to an example embodiment of the present inventive concepts may include disposing the semiconductor package 100a on an upper surface of the film 20 on which the coating layer 80 is formed on a portion (e.g., near an edge of the hole 31) of an upper surface of the film 20, so that a portion (e.g., lower portion) of the semiconductor package 100a is in contact with a side surface of the coating layer 80, and forming a conductive shielding layer 170 of which a portion (e.g., lower portion) thereof covers the other portion (e.g., upper portion) of the semiconductor package 100a in contact with the side surface of the coating layer 80.

Referring to FIG. 3A, a method of manufacturing a semiconductor package 100-4b may include forming a coating layer 80 on a film 20 on which the semiconductor package 100a of FIG. 2C is disposed. The coating layer 80 may not cover an upper surface of the semiconductor package 100a. For example, the upper surface of the semiconductor package 100a may be temporarily covered by a mask layer or a material of the coating layer 80 when the coating layer 80 is formed. Alternatively or additionally, the coating layer 80 may be implemented as an adhesive tape having a hole of the same size as a lower surface of the semiconductor package 100a, and may be temporarily attached to the film 20. For example, the coating layer 80 may include a material which has high flexibility and is efficient to process such as polyimide, or may be an adhesive polymer or an ultraviolet ray tape, but the present inventive concepts are not limited thereto.

Referring to FIGS. 3B and 3C, a method of manufacturing semiconductor packages 100-5b and 100-6b may include forming a conductive shielding layer 170, and separating a semiconductor package 100a from a film 20 according to a sputtering process. A sputtering device 71 may deposit conductive materials on a surface of a portion of the semiconductor package 100a located at an upper level than the coating layer 80. In some example embodiments, some conductive materials 70 provided by the sputtering device 71 may be deposited on an upper surface of the coating layer 80. Accordingly, a surface of a portion of the semiconductor package 100a located on or below the coating layer 80 may not be covered by the conductive materials 70.

Since a formation height of the conductive shielding layer 170 may be adjusted by adjusting a thickness of the coating layer 80, the formation height thereof may be finely adjusted (or may be adjusted). In the method of manufacturing semiconductor packages 100-1, 100-2, 100-3, 100-4b, 100-5b, and 100-6b according to an example embodiment of the present inventive concepts, since the formation height of the conductive shielding layer 170 may be finely adjusted (or may be adjusted), since the structure in which the conductive shielding layer 170 is connected to a ground of the semiconductor package 100a while exposing a lower side surface of the wiring structure of the semiconductor package 100a may be stably formed (or may be formed), electromagnetic shielding reliability of the semiconductor package 100a may be improved.

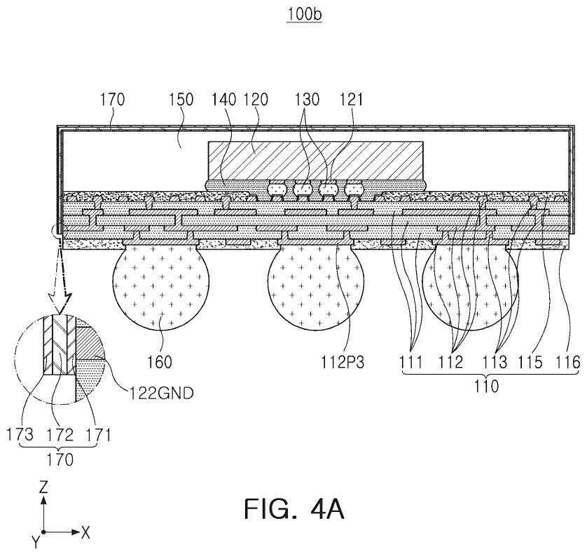

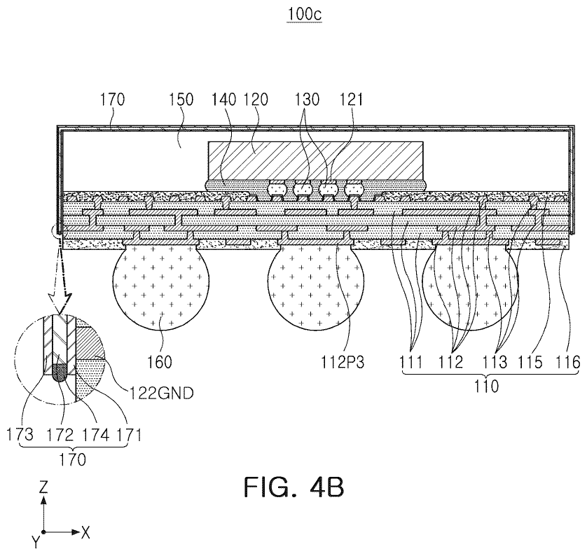

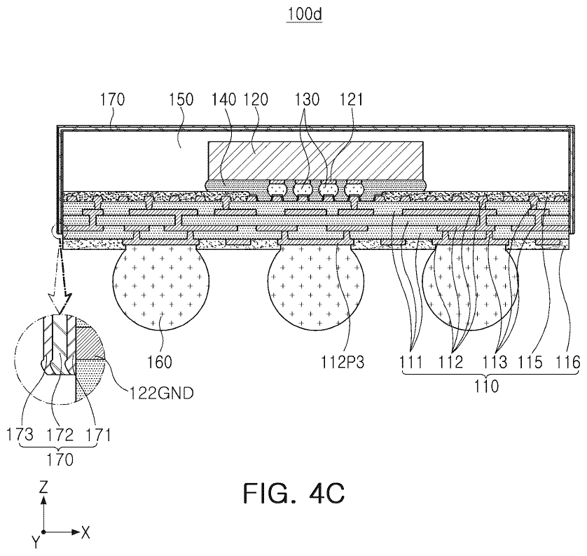

Referring to FIGS. 4A to 4C, the conductive shielding layer 170 of the semiconductor package 100b, 100c, and 100d according to an example embodiment of the present inventive concepts may include at least a portion of a first conductive shielding layer 171, a second conductive shielding layer 172, and a third conductive shielding layer 173. The first, second, and third conductive shielding layers 171, 172, and 173 may be formed sequentially.

The first conductive shielding layer 171 may directly contact a portion of a side surface of the wiring structure 110. For example, the first conductive shielding layer 171 may directly contact an encapsulant 150, and may include a material (e.g., stainless steel) which is advantageous for being stably disposed (or for being disposed) on a surface of the wiring structure 110 and/or encapsulant 150 and is effective (or beneficial) to be used in a sputtering process.

The second conductive shielding layer 172 may directly contact the first conductive shielding layer 171 and cover the first conductive shielding layer 171. The second conductive shielding layer 172 may include a conductive material (e.g., copper) different from conductive materials (e.g., stainless steel) included in the first and third conductive shielding layers 171 and 173. For example, the material (e.g., copper) of the second conductive shielding layer 172 has high conductivity, so that the material may improve shielding performance, and may be efficiently used in a sputtering process.

The third conductive shielding layer 173 may directly contact the second conductive shielding layer 172 and cover the second conductive shielding layer 172. The third conductive shielding layer 173 may include a material (e.g., stainless steel) having better robustness against an external environment than the second conductive shielding layer 172.

At least according to the semiconductor package manufacturing method of FIGS. 2A to 3C, a portion of a surface of the second conductive shielding layer 172 may not be covered by the first and third conductive shielding layers 171 and 173. For example, since the second conductive shielding layer 172 may be formed after the first conductive shielding layer 171 is formed in a state in which an edge of the first conductive shielding layer 171 is not exposed, the edge of the first conductive shielding layer 171 may not be covered by the second conductive shielding layer 172. For example, since the third conductive shielding layer 173 may be formed after the second conductive shielding layer 172 is formed in a state in which edges of the first and second conductive shielding layers 171 and 172 are not exposed, the edges of the first and second conductive shielding layers 171 and 172 may not be covered by the third conductive shielding layer 173.

Referring to FIG. 4B, a portion 174 of a surface of the second conductive shielding layer 172, not covered by the first and third conductive shielding layers 171 and 173 may have characteristics due to exposure. For example, the portion 174 may include an oxide of a conductive material (e.g., copper) included in the second conductive shielding layer 172. For example, the portion 174 may have a state in which a conductive material (e.g., stainless steel) included in the first and third conductive shielding layers 171 and 173 and a conductive material (e.g., copper) included in the second conductive shielding layer 172 are mixed.

Referring to FIG. 4C, a lower edge portion of the conductive shielding layer 170 may include a portion thicker than a thickness of the remaining portion of the conductive shielding layer 170. For example, the liquid 60 of FIGS. 2D to 2F or the coating layer 80 of FIGS. 3A to 3C may have a relatively greater influence (or may have a greater influence) on thickness variability of the portion of the conductive shielding layer 170, close to the liquid 60 or the coating layer 80. Accordingly, the thickest portion of the conductive shielding layer 170 may be located at the lower edge portion of the conductive shielding layer 170.

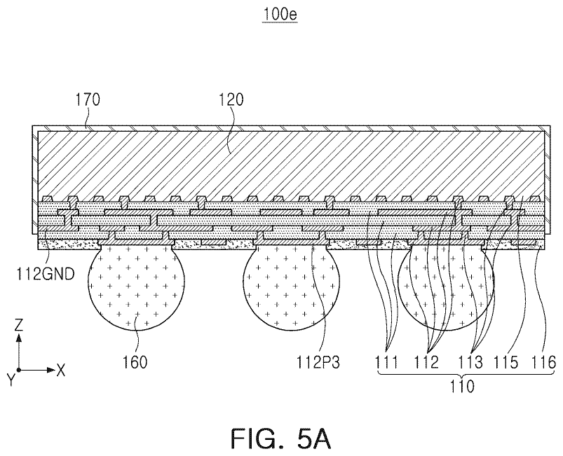

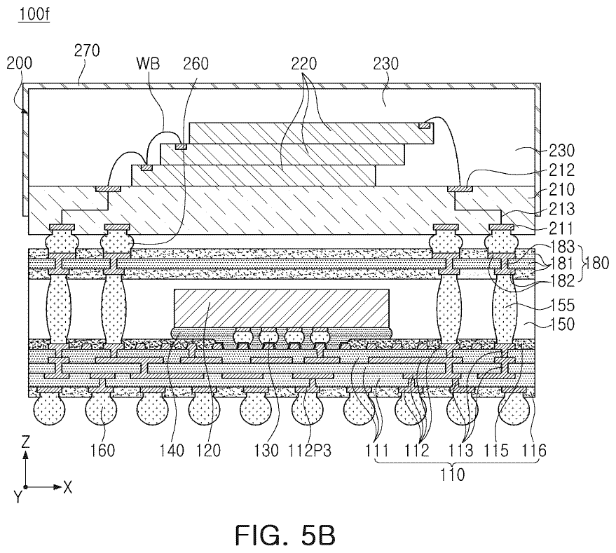

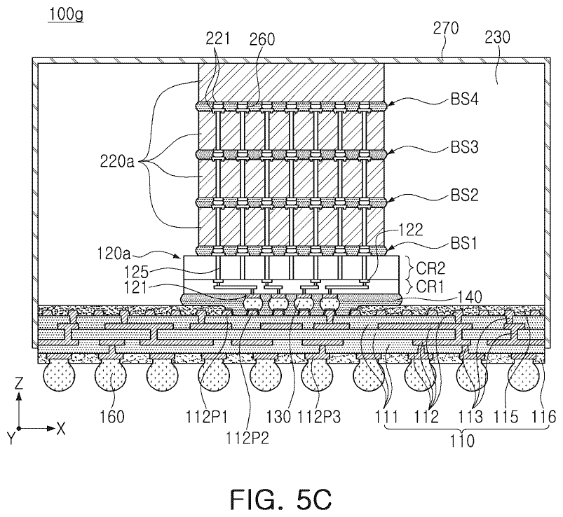

Referring to FIG. 5A, a semiconductor package 100e according to an example embodiment of the present inventive concepts may have a structure in which the conductive shielding layer 170 is in direct contact with the semiconductor chip 120, and may not include at least one of an encapsulant, chip bumps, and non-conductive film layers. For example, since the semiconductor package 100e may have a fan-in structure, a horizontal area of the semiconductor chip 120 may be substantially equal to a horizontal area of the wiring structure 110. Accordingly, the wiring layers 112 of the wiring structure 110 may include a redistribution line with a finer line width/pitch than a wiring of a general printed circuit board.

Referring to FIG. 5B, a semiconductor package 100f according to an example embodiment of the present inventive concepts, as compared to the semiconductor package 100a described above with reference to FIG. 1, may further include conductive posts 170, a substrate 180 on the conductive posts 170, and an upper package 200 on the substrate 180. The upper package 200 may include a wiring structure 210, additional semiconductor chips 220, an encapsulant 230, and a plurality of bumps 260.

The conductive posts 170 may be disposed between the wiring structure 110 and the substrate 180, to electrically connect the wiring structure 110 and the substrate 180. The conductive posts 170 may extend in a vertical direction, for example, a Z-direction, between the wiring structure 110 and the substrate 180, to provide a vertical connection path electrically connecting the wiring layer 112 and the upper wiring layer 182. The conductive posts 170 may include, for example, tin (Sn), indium (In), bismuth (Bi), antimony (Sb), copper (Cu), silver (Ag), zinc (Zn), lead (Pb), or an alloy including thereof, and may have a spherical or ball shape extending in the z direction, but example embodiments are not limited thereof.

The substrate 180 is a substrate providing a wiring layer on an upper surface of the first package 100f, and may be disposed between a lower package and an upper package in a Package on Package (POP) structure. The substrate 180 may include upper insulating layers 181, upper wiring layers 182, and wiring vias 183. Since each of the upper insulating layers 181, the upper wiring layers 182, and the wiring vias 183 has the same or similar characteristics as those of the insulating layers 111, the wiring layers 112, and the wiring vias 113 described above, overlapping descriptions are omitted. The uppermost and lowermost upper layers among the upper insulating layers 181 may be a solder mask layer protecting upper interconnection layers 132, and include openings exposing at least a portion of the upper wiring layers 132.

The wiring structure 210 may include upper pads 212 and lower pads 211 exposed through the upper and lower surfaces. The wiring structure 210 may include, for example, silicon (Si), glass, ceramic, or plastic. The wiring structure 210 may include an electrical path 213 formed by wiring patterns therein, and the wiring patterns may have a multi-layer structure.

Additional semiconductor chips 220 may include a logic semiconductor chip and/or a memory semiconductor chip. A device layer is disposed below the additional semiconductor chips 220, so that a lower surface thereof may be active surface, but a dispositional position of the active surface may vary in various example embodiments. The additional semiconductor chips 220 may be mounted on the wiring structure 210 by wire bonding or flip chip bonding. For example, a plurality of additional semiconductor chips 220 may be stacked on the wiring structure 210 in a vertical direction, and electrically connected to an upper pad 212 of the wiring structure 210 by a bonding wire WB. For example, the additional semiconductor chips 220 may include a memory chip, and the semiconductor chip 120 may include an AP chip.

The encapsulant 230 may be disposed to surround the additional semiconductor chips 220, and may serve to protect the additional semiconductor chips 220. The encapsulant 230 may be formed of, for example, a silicone-based material, a thermosetting material, a thermoplastic material, or a UV-treated material, but example embodiments are not limited thereof.

The plurality of bumps 260 may be disposed on a lower surface of the wiring structure 210, and may be connected to at least a portion of the lower pads 211. The plurality of bumps 260 may connect the upper package 200 to a lower package, and thereby, a Package on Package (PoP) structure may be implemented. Since the plurality of bumps 260 may be implemented similarly to the plurality of bumps 160, the plurality of bumps 260 may have a melting point lower than that of the lower pads 211, but the present inventive concepts are not limited thereto.

The conductive shielding layer 270 may accommodate at least one of the additional semiconductor chips 220, cover the encapsulant 230, cover a portion of a side surface of the wiring structure 210, and not cover the other portion of the side surface of the wiring structure 210, which may be exposed.

Referring to FIG. 5C, unlike the embodiment of FIG. 1, a semiconductor package 100g according to an example embodiment of the present inventive concepts, may further include a plurality of additional semiconductor chips 220a disposed to be stacked on a semiconductor chip 120a of the wiring structure 110. For example, the semiconductor package 100g may be a System in Package (SIP), the semiconductor chip 120a may be a logic semiconductor chip, and the additional semiconductor chips 220a may be memory semiconductor chips.

The semiconductor chip 120a of the present example embodiment may have a lower first region CR1 and an upper second region CR2, and may further include device layers 122 and through-vias 125. The first region CR1 may be a device region, and may be a region in which devices such as transistors and/or memory cells forming a semiconductor chip are formed based on the second region CR2. The second region CR2 may be a substrate region and, for example, may be a region including a semiconductor material such as silicon (Si).

The device layers 122 may be disposed in the first region CR1 to comprise the devices. The through-vias 125 may penetrate through the second region CR2 of the semiconductor chip 120a. In some example embodiments, the through-vias 125 may further penetrate through at least a portion of the first region CR1. The through-vias 125 may be electrically connected to the device layers 122 of the first region CR1, and may provide an electrical connection between additional semiconductor chips 220a and the wiring structure 110. The through-vias 125 may be formed of a conductive material, and may include, for example, at least one of tungsten (W), aluminum (Al), and copper (Cu).

The additional semiconductor chips 220a may be stacked and disposed on the semiconductor chip 120a in a Z-direction. The additional semiconductor chips 220a may include through-vias 125 except for the uppermost additional semiconductor chip 220a. A first connection region BS1 may be formed between the semiconductor chip 120a and the additional semiconductor chip 220a, and second to fourth connection regions BS2, BS3, and BS4 may be located between the second semiconductor chips 220a, respectively. Although not specifically shown, at least a portion of the first to fourth connection regions BS1, BS2, BS3, and BS4 may have substantially the same structure as that of a connection region between the wiring structure 110 and the semiconductor chip 120a.

For example, in each of the first to fourth connection regions BS1, BS2, BS3, and BS4, the plurality of bumps 260 may be connected between a plurality of second pads 221 of each of the additional semiconductor chips 220a, and may be implemented similarly to the plurality of chip bumps 130, so that the plurality of bumps 260 may have a lower melting point than a melting point of the plurality of second pads 221, but the present inventive concepts are not limited thereto.

The conductive shielding layer 270 may accommodate the semiconductor chip 120a and additional semiconductor chips 220, cover the encapsulant 230, and cover a portion of the side surface of the wiring structure 210, but not cover the other portion of the side surface of the wiring structure 210 and be exposed.

As set forth above, according to an example embodiment of the present inventive concepts, a semiconductor package and a method of manufacturing a semiconductor package may improve electromagnetic shielding reliability.

For example, the semiconductor package and the method of manufacturing a semiconductor package according to an example embodiment of the present inventive concepts may prevent (or reduce the likelihood of having) a separated/cut portion (e.g., edge portion) in a process of forming a structure for electromagnetic shielding (e.g., conductive shielding layer) from becoming physical vulnerability (e.g., burring), so electromagnetic shielding reliability (e.g., durability of the conductive shielding layer or connectivity to ground) can be improved.

While example embodiments have been shown and described above, it will be apparent to those skilled in the art that modifications and variations could be made without departing from the scope of the present inventive concepts as defined by the appended claims.

What is claimed is:

1. A semiconductor package, comprising:
a wiring structure having a structure in which at least one insulating layer and at least one wiring layer are alternately stacked;
a semiconductor chip arranged to vertically overlap the wiring structure; and
a conductive shielding layer accommodating the semiconductor chip, and covering a portion of a side surface of the wiring structure to be connected to a ground of the at least one wiring layer,
wherein another portion of the side surface of the wiring structure is not covered by the conductive shielding layer.

2. The semiconductor package of claim 1, further comprising:
a plurality of bumps electrically connected to the at least one wiring layer and arranged below the at least one insulating layer,
wherein a portion of a side surface of the at least one insulating layer is not covered by the conductive shielding layer.

3. The semiconductor package of claim 2, wherein the wiring structure further comprises a lower solder mask layer having a plurality of vertical passages through which the plurality of bumps are electrically connected to the at least one wiring layer,
wherein the portion of the side surface of the at least one insulating layer, not covered by the conductive shielding layer is arranged above a side surface of the lower solder mask layer.

4. The semiconductor package of claim 2, wherein a diameter of each of the plurality of bumps exceeds 200 μm.

5. The semiconductor package of claim 1, wherein the conductive shielding layer comprises
a first conductive shielding layer contacting the portion of the side surface of the wiring structure;
a second conductive shielding layer contacting the first conductive shielding layer and covering the first conductive shielding layer; and
a third conductive shielding layer contacting the second conductive shielding layer and covering the second conductive shielding layer,
wherein the second conductive shielding layer includes a conductive material that is different from conductive materials included in the first and third conductive shielding layers.

6. The semiconductor package of claim 5, wherein a portion of a surface of the second conductive shielding layer is not covered by the first and third conductive shielding layers.

7. The semiconductor package of claim 6, wherein the portion of the surface of the second conductive shielding layer, not covered by the first and third conductive shielding layers, comprises an oxide of the conductive material included in the second conductive shielding layer.

8. The semiconductor package of claim 6, wherein in the portion of the surface of the second conductive shielding layer, not covered by the first and third conductive shielding layers, the conductive materials included in the first and third conductive shielding layers and the conductive material included in the second conductive shielding layer are mixed.

9. The semiconductor package of claim 1, wherein a lower edge portion of the conductive shielding layer comprises a portion thicker than a thickness of a remaining portion of the conductive shielding layer.

10. The semiconductor package of claim 1, further comprising:
an encapsulant encapsulating the semiconductor chip on an upper surface of the wiring structure,
wherein the conductive shielding layer contacts an upper surface and a side surface of the encapsulant.

11. The semiconductor package of claim 10, further comprising:
at least one additional semiconductor chip vertically overlapping the semiconductor chip and the at least one additional semiconductor chip is encapsulated by the encapsulant.

12. A method of manufacturing a semiconductor package, the method comprising:
disposing a semiconductor package so that a portion of the semiconductor package on which a conductive shielding layer is not formed is immersed in liquid; and
forming the conductive shielding layer on another portion of the semiconductor package, such that a portion of the conductive shielding layer covers the another portion of the semiconductor package immersed in liquid.

13. The method of manufacturing a semiconductor package of claim 12, wherein the disposing the semiconductor package comprises
disposing the semiconductor package on a portion of an upper surface of a film to be immersed in the liquid.

14. The method of manufacturing a semiconductor package of claim 13, wherein the disposing the semiconductor package comprises
disposing the semiconductor package to vertically overlap a hole of the film having the hole, so as to insert a plurality of bumps of the semiconductor package into the hole.

15. The method of manufacturing a semiconductor package of claim 14, wherein the disposing the semiconductor package comprises
disposing a combination of the semiconductor package and the film on an upper surface of a support member immersed in the liquid.

16. The method of manufacturing a semiconductor package of claim 12, wherein the forming the conductive shielding layer comprises
forming the conductive shielding layer according to a sputtering process.

17. The method of manufacturing a semiconductor package of claim 12, wherein the liquid is water containing a surfactant.

18. A method of manufacturing a semiconductor package, the method comprising:
disposing a semiconductor package on an upper surface of a film on which a coating layer is formed on a portion of the upper surface, so that a portion of the semiconductor package is in contact with a side surface of the coating layer; and
forming a conductive shielding layer to cover another portion of the semiconductor package that is not in contact with the side surface of the coating layer.

19. The method of manufacturing a semiconductor package of claim 18, wherein the disposing the semiconductor package comprises
disposing the semiconductor package to vertically overlap a hole of the film having the hole, so as to insert a plurality of bumps of the semiconductor package into the hole.

20. The method of manufacturing a semiconductor package of claim 18, wherein the forming the conductive shielding layer comprises
forming the conductive shielding layer according to a sputtering process.
